(19) United States
(12) Patent Application Publication
(10) Pub. No.: US 2015/0357502 A1
(43) Pub. Date: Dec. 10, 2015

(54) GROUP IIB-VIA COMPOUND SOLAR CELLS WITH MINIMUM LATTICE MISMATCH AND REDUCED TELLURIUM CONTENT

(71) Applicant: Encoresolar, Inc., Saratoga, CA (US)

(72) Inventor: Bulent M. BASOL, Manhattan Beach, CA (US)

(21) Appl. No.: 14/732,419

(22) Filed: Jun. 5, 2015

Related U.S. Application Data
(60) Provisional application No. 61/997,565, filed on Jun. 5, 2014.

(51) Int. Cl. H01L 31/073; H01L 31/0296; H01L 31/0224; H01L 31/18

(52) U.S. Cl. CPC H01L 31/073; H01L 31/1832; H01L 31/02966; H01L 31/022466

(57) ABSTRACT

A thin film solar cell structure is disclosed, the solar cell structure comprising a CdSeₓS₍₁₋ₓ₎ junction partner layer forming a hetero-interface with a CdSe_{y}Te_{(1-y)} absorber layer, where the value of “x” is larger than or equal to zero and smaller than or equal to about 0.5, and where the value of “y” is larger than or equal to about 0.7 and smaller than or equal to about 0.8. A method of fabricating a solar cell is also disclosed, the method comprising: depositing a CdSeₓS₍₁₋ₓ₎ junction partner film, and providing a CdSe_{y}Te_{(1-y)} absorber layer to form a hetero-interface between the CdSeₓS₍₁₋ₓ₎ junction partner film and the CdSe_{y}Te_{(1-y)} absorber layer, wherein a value of “x” is larger than or equal to zero and smaller than or equal to about 0.5, and wherein a value of “y” is larger than or equal to about 0.7 and smaller than or equal to about 0.8.

### INTRODUCTION

Cadmium telluride (CdTe) is a Group IIB-VIA compound semiconductor with application in photovoltaics (PV). CdTe solar cells with near 20% conversion efficiency have been demonstrated in the laboratory and a solar module with 17% efficiency has also been fabricated. One of the biggest challenges for CdTe devices for effectively participating in the ever-growing PV market is the limited availability of tellurium (Te), which is a rare element. At the present time typical high efficiency CdTe solar cells have an absorber thickness of 3000-6000 nm. Assuming a 15% module efficiency, it has been calculated that the existing worldwide Te production would allow the CdTe technology manufacturing to be limited to below 10 GW/year. Considering the fact that the world PV market is expected to grow beyond 50 GW/year in just 2-3 years, limited Te availability is a serious setback for the CdTe technology. To address this issue, research groups have been working on approaches to reduce the thickness of the CdTe absorber of the device to around 1000 nm. However, reduction of the film thickness typically introduces problems such as pinhole generation and reduction in conversion efficiency. Also the thin absorber device structure requires the use of a near-intrinsic CdTe layer. As deposited CdTe layers may be obtained as near-intrinsic high resistivity films. However, the electronic properties of such as-deposited layers are inferior due to the low carrier lifetimes, which result from high density of defects in the as-deposited material. Post deposition process steps such as Cl treatment (chloride treatment) at elevated temperatures and p-type doping improve the electronic properties of thin CdTe layers, but at the same time, they lower the resistivity of the material away from the intrinsic state. Another issue in the prior art CdS/CdTe heterojunction solar cell structure is the rather large (about 10%) lattice mismatch at the hetero-interface or junction. Such mismatch reduces the efficiency of the solar cells and modules, especially during mass production. Therefore, there is great need to develop approaches in thin film solar module manufacturing that will reduce lattice mismatch at the junction of the devices, reduce the Te usage in the process and provide a material with good electronic properties.

### DETAILED DESCRIPTION OF THE INVENTION

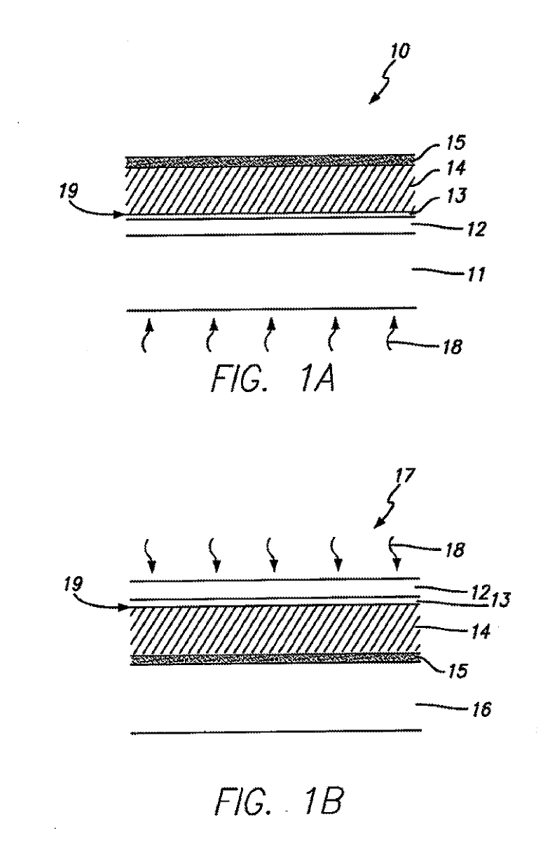

FIGS. 1A and 1B show two solar cell structures that may be fabricated, using the teachings of the present inventions. FIG. 1A is a “super-strate” structure, wherein light enters the active layers of the device through a transparent sheet 11. The transparent sheet 11 serves as the support on which the active layers are deposited. In fabricating the “super-strate” structure 10, a transparent conductive layer (TCL) 12 may first be deposited on the transparent sheet 11. Then a CdSeₓS₍₁₋ₓ₎ junction partner film or layer 13 may be deposited over the TCL 12, wherein a value of “x” may range between 0 and 0.5. A CdSe_{y}Te_{(1-y)} absorber film 14 may next be formed over the junction partner layer 13, wherein a value of “y” may range between 0.7 and 0.8. Then an ohmic contact layer 15 may be deposited over the CdSe_{y}Te_{(1-y)} absorber film 14, completing the solar cell. As shown by arrows 18 in FIG. 1A, light enters this device through the transparent sheet 11. In the “super-strate” structure 10 of FIG. 1A, the transparent sheet 11 may be glass or a material (e.g., a high temperature polymer such as polyimide) that has high optical transmission (such as higher than 80%) in the visible spectra of the sun light. The TCL 12 is usually a transparent conductive oxide (TCO) layer comprising any one of tin-oxide, cadmium-tin-oxide, indium-tin-oxide, and zinc-oxide, which may be doped to increase their conductivity. Multi layers of these TCO materials as well as their alloys or mixtures may also be utilized in the TCL 12. The ohmic contact 15 may comprise highly conductive metals such as Mo, Ni, Cr, Ti, Al, or a doped transparent conductive oxide such as the TCOs mentioned above. The rectifying junction, which is the heart of this device, is located near an hetero-interface 19 between the CdSe_{y}Te_{(1-y)} absorber film 14 and the CdSeₓS₍₁₋ₓ₎ junction partner layer 13.

FIG. 1B depicts a “sub-strate” structure 17, wherein the light enters the device through a transparent conductive layer deposited over the CdSe_{y}Te_{(1-y)} absorber film, which is grown over a substrate. In the “sub-strate” structure 17 of FIG. 1B, the ohmic contact layer 15 is first deposited on a sheet substrate 16, and then the CdSe_{y}Te_{(1-y)} absorber film 14 is formed on the ohmic contact layer 15. This is followed by the deposition of the CdSeₓS₍₁₋ₓ₎ junction partner layer 13 and the transparent conductive layer (TCL) 12 over the CdSe_{y}Te_{(1-y)} absorber film 14. As shown by arrows 18 in FIG. 1B, light enters this device through TCL 12. There may also be finger patterns (not shown) on the TCL 12 to lower the series resistance of the solar cell. The sheet substrate 16 does not have to be transparent in this case. Therefore, the sheet substrate 16 may comprise a sheet or foil of metal, glass or polymeric material.

As can be seen from FIG. 1A and FIG. 1B, present inventions provide a thin film heterojunction device structure of the type CdSeₓS₍₁₋ₓ₎/CdSe_{y}Te_{(1-y)}, wherein the value of “x” may range between 0 and 0.5 and the value of “y” may range between 0.7 and 0.8. A device structure of the present inventions comprising an absorber layer with a composition wherein the Se/(Se+Te) ratio is in the specific range of 0.7-0.8 offers unique advantages compared to the prior art CdS/CdTe cell structure. These advantages include, but are not limited to the following factors:

1) The CdSe_{y}Te_{(1-y)} absorber has an optical bandgap of 1.45-1.52 eV, which is very close to the bandgap of pure CdTe. This is a unique property of this material. Despite the fact that 70-80 percent of Te is replaced by Se, the bandgap of the new alloy containing Se still has a bandgap value of around 1.5 eV, which is equivalent to the bandgap value of CdTe. It should be noted that 1.5 eV is near the theoretically calculated bandgap value of a thin film absorber for the highest solar cell conversion efficiency, and therefore is very desirable. The bandgap of the CdSe_{y}Te_{(1-y)} material increases beyond 1.52 eV if the value of “y” is larger than 0.8, and it decreases from 1.45 eV to about 1.35 eV as the value of “y” is decreased from 0.7 to 0.4. Therefore, the compositions with x<0.7 and x>0.8 may not be desirable for high efficiency solar cell fabrication.

2) As a portion of the Te in CdTe is replaced by Se, the lattice constant of the material gets reduced. For example, the lattice constant of CdTe is about 6.48 angstroms, whereas the lattice constant of CdSe is about 6.05 angstroms. For compositions between CdTe and CdSe the lattice constant values vary between 6.48 and 6.05. For the prior art device structure of CdS/CdTe the lattice mismatch at the hetero-junction interface is about 10% considering the fact that the lattice constant of CdS is about 5.83 angstroms, i.e. lattice mismatch=(6.48-5.83)/6.48. For the CdSeₓS₍₁₋ₓ₎/CdSe_{y}Te_{(1-y)}, structures of the present inventions the lattice constant of CdSeₓS₍₁₋ₓ₎ may increase from about 5.83 to about 5.94 as x increases from 0 to 0.5, and the lattice constant of CdSe_{y}Te_{(1-y)} may range from about 6.18 to about 6.14 with y values ranging from 0.8 to 0.7, respectively. As a result, the lattice mismatch at the CdSeₓS₍₁₋ₓ₎/CdSe_{y}Te_{(1-y)} junction of the present inventions may be greatly reduced, to a range of 3.2%-5.7%. This drastically reduced lattice mismatch in thin film solar cells increases device voltage and current and the conversion efficiency.

3) As a portion of the Te in the CdTe layer is replaced by Se, the electron effective mass in the material decreases. For example in CdTe the electron effective mass is about 0.195 m₀, whereas in CdSe this value is about 0.15 m₀, where m₀ is true mass of electron (˜10⁻³⁰ kg). For a CdSe_{y}Te_{(1-y)} absorber with “y” value between 0.7 and 0.8 the electron effective mass may be in the 0.155-0.16 m₀ range. Lower electron effective mass compared to CdTe provides higher electron mobility and longer electron lifetime values in the CdSe_{y}Te_{(1-y)} absorber layer of the present inventions, and it results in improved solar cell efficiency.

4) In addition to the technical benefits listed above, replacement of 70-80% of the Te amount in a CdTe layer with a more abundant material, Se, provides a 3.5-5 times expansion possibility in the manufacturing volume. Whereas, only about 10 GW/year of manufacturing may be possible using the prior art CdTe absorbers due to the limited availability of Te, this manufacturing volume may be increased to 35-50 GW with the structure of the present inventions even if the absorber thickness and the efficiency of the device were left the same. It should be noted that the improved efficiency of the devices due to the technical factors listed above may increase the manufacturing volume well above the 50 GW/yr level.

5) As explained before, a highly attractive high efficiency CdTe device structure employs a CdTe layer with a thickness in the range of 700-1200 nm. Although, theoretical modeling demonstrated the possibility of near 20% device efficiency for such a cell, practical devices fabricated with this absorber thickness always yielded efficiency values less than those with thicker CdTe layers. One reason for this may be the fact that the thin CdTe device structure requires a near intrinsic absorber layer with good electronic properties such as a high (mobility*lifetime) product. The prior art CdTe aborbers may not be able to deliver these requirements. The CdSe_{y}Te_{(1-y)} absorber of the present inventions, on the other hand, provides these properties because: i) it has high carrier mobility and long carrier lifetime, therefore good electronic properties, and, ii) it can be made near-intrinsic because CdSe is easy to make n-type but very difficult to make p-type. CdTe, on the other hand may be doped p-type. Therefore, a solid solution of CdTe and CdSe, when doped with a p-type dopant may yield a material that has a higher resistivity (or near-intrinsic) and at the same time better electronic quality compared to CdTe under the same heat treatment and doping conditions. A high efficiency CdSeₓS₍₁₋ₓ₎/CdSe_{y}Te_{(1-y)} device with a 700-1200 nm thick CdSe_{y}Te_{(1-y)} absorber layer may further increase the over 50 GW/yr manufacturing volume to well above 150 GW/yr.

Several different approaches may be used to form the CdSeₓS₍₁₋ₓ₎ and the CdSe_{y}Te_{(1-y)} layers of the present inventions. The CdSeₓS₍₁₋ₓ₎ layer may be formed by co-deposition of CdS and CdSe with the target ratio (CdSe/(CdS+CdSe) atomic ratio of less than or equal to 0.5) using methods such as chemical bath deposition, electrodeposition, atomic layer deposition, evaporation, sputtering, close space sublimation and vapor transport. A preferred method comprises formation of a CdS/CdSe or CdSe/CdS stack followed by a heat treatment, which causes diffusion between the CdS and the CdSe films and formation of the CdSeₓS₍₁₋ₓ₎ ternary solid solution. Another preferred method involves heat treatment of a CdS film in a Se vapor containing environment or heat treatment of a CdSe film in a S vapor containing environment. The CdSe_{y}Te_{(1-y)} layer may be formed by co-deposition of CdTe and CdSe with the target ratio (CdSe/(CdTe+CdSe) atomic ratio between 0.7 and 0.8) using methods such as chemical bath deposition, electrodeposition, evaporation, sputtering, close space sublimation, ink printing and vapor transport. A preferred method comprises formation of a CdTe/CdSe or CdSe/CdTe stack followed by a heat treatment, which causes diffusion between the CdTe and the CdSe films and formation of the CdSe_{y}Te(_{i-y}) ternary solid solution. It is also possible to heat treat a CdTe layer in a Se containing environment to cause Se diffusion into the material and formation of the solid solution or heat treat a CdSe layer to react it with a Te source such as a layer of Te.

An exemplary process flow to fabricate a solar cell comprising a thin film heterojunction device structure of the type CdSeₓS₍₁₋ₓ₎/CdSe_{y}Te_{(1-y)}, wherein x may range between 0 and 0.5 and y may range between 0.7 and 0.8 may comprise the steps of; i) deposition of a transparent conductive layer such as a transparent conductive oxide (TCO) film on a transparent superstrate such as glass; ii) deposition of a thin, preferably <200 nm, more preferably <100 nm thick, CdSeₓS₍₁₋ₓ₎ junction partner film over the transparent conductive layer; iii) deposition of a CdSe_{y}Te_{(1-y)} absorber layer, iv) heat treatment in presence of Cl, such as in presence of cadmium chloride in a temperature range of 350-450 C, v) doping using a dopant such as Cu and Sb by depositing a dopant source film over the absorber layer and driving in the dopant by heat treatment, and, vi) deposition of a back contact over the doped absorber layer.

A preferred process flow may comprise the steps of; i) deposition of a transparent conductive layer such as a transparent conductive oxide (TCO) film on a transparent sheet such as glass, ii) deposition of a thin, preferably <200 nm, more preferably <100 nm thick, CdSeₓS₍₁₋ₓ₎ junction partner film over the transparent conductive layer, iii) deposition of a stack comprising at least one sub-layer of CdSe and at least one sub-layer of CdTe with the targeted “y” value, iv) heat treatment in presence of Cl, such as in presence of cadmium chloride in a temperature range of 350-500 C, thus causing reaction and inter-diffusion between the sub-layers within the stack and forming a CdSe_{y}Te_{(1-y)} absorber layer, v) depositing a copper source, such as a copper selenide, copper telluride or a copper salt (such as copper halide) film, on the exposed surface of the CdSe_{y}Te_{(1-y)} absorber layer , vi) heat treating at a temperature range of 150-350 C, and vii) deposition of a back contact over the doped absorber layer.

In one preferred embodiment the thickness of the absorber layer may be in the range of 1500-3000 nm. In another preferred embodiment the thickness of the absorber layer may be in the range of 700-1200 nm.

What is claimed is:

1. A thin film solar cell structure comprising a CdSeₓS₍₁₋ₓ₎ junction partner layer forming a hetero-interface with a CdSe_{y}Te_{(1-y)} absorber layer, wherein the value of “x” is larger than or equal to zero and smaller than or equal to about 0.5, and wherein the value of “y” is larger than or equal to about 0.7 and smaller than or equal to about 0.8.

2. The solar cell structure of claim 1 wherein a lattice mismatch at the hetero-interface is less than about 5.7% and the bandgap of the CdSe_{y}Te_{(1-y)} absorber layer is in the range of 1.45-1.52 eV.

3. The thin film solar cell structure of claim 2 wherein the CdSeₓS₍₁₋ₓ₎ junction partner layer is disposed over a transparent conductive layer and there is an ohmic contact over the CdSe_{y}Te_{(1-y)} absorber layer.

4. The thin film solar cell structure of claim 3 wherein the thickness of the CdSeₓS₍₁₋ₓ₎ junction partner layer is less than 200 nm and the thickness of the CdSe_{y}Te_{(1-y)} absorber layer is in the range of 700-1200 nm.

5. The thin film solar cell structure of claim 3 wherein the thickness of the CdSeₓS₍₁₋ₓ₎ junction partner layer is less than 200 nm and the thickness of the CdSe_{y}Te_{(1-y)} absorber layer is in the range of 1500-3000 nm.

6. A method of fabricating a solar cell comprising:
depositing a CdSeₓS₍₁₋ₓ₎ junction partner film, and
providing a CdSe_{y}Te_{(1-y)} absorber layer to form a hetero-interface between the CdSeₓS₍₁₋ₓ₎ junction partner film and the CdSe_{y}Te_{(1-y)} absorber layer, wherein
a value of “x” is larger than or equal to zero and smaller than or equal to about 0.5, and wherein a value of “y” is larger than or equal to about 0.7 and smaller than or equal to about 0.8.

7. The method of claim 6 wherein the step of providing the CdSe_{y}Te_{(1-y)} absorber layer comprises forming a stack comprising at least one sub-layer of CdSe and at least one sub-layer of CdTe and reacting the at least one sub-layer of CdSe with the at least one sub-layer of CdTe, wherein an atomic ratio of CdSe/(CdTe+CdSe) in the stack is in the range of 0-7-0.8.

8. The method of claim 7 wherein the step of reacting is carried out in presence of Cl using a Cl source.

9. The method of claim 8 wherein the Cl source is a CdCl₂ layer deposited over the stack and the step of reacting is performed at a temperature range of 350-500 C.

10. The method of claim 8 further comprising a step of depositing a Cu source over the CdSe_{y}Te_{(1-y)} absorber layer and heat treating at a temperature range of 150-350 C, wherein the Cu source comprises a Cu compound.
